(19) United States
(12) Patent Application Publication
(10) Pub. No.: US 2022/0165568 A1
(43) Pub. Date: May 26, 2022

(54) METHOD AND DEVICE FOR FORMING HEXAGONAL BORON NITRIDE FILM

(71) Applicant: TOKYO ELECTRON LIMITED, Tokyo (JP)

(72) Inventors: Nobutake KABUKI, Yamanashi (JP); Masahito SUGIURA, Yamanashi (JP); Takashi MATSUMOTO, Yamanashi (JP); Kenjiro KOIZUMI, Yamanashi (JP); Ryota IFUKU, Yamanashi (JP)

(21) Appl. No.: 17/438,132

(22) PCT Filed: Feb. 19, 2020
(86) PCT No.: PCT/JP2020/006483

§ 371 Date: Sep. 10, 2021

(30) Foreign Application Priority Data
Mar. 15, 2019 (JP) 2019-048333

(51) Int. Cl. H01L 21/02; C23C 16/34; C23C 16/505; H01J 37/32

(52) U.S. Cl. CPC H01L 21/02274; C23C 16/342; H01L 21/02112; H01J 37/32357; C23C 16/505

(57) ABSTRACT

A method for forming a hexagonal boron nitride film comprises: providing a substrate; and generating plasma of a boron-containing gas and a nitrogen-containing gas in a plasma generation region located at a position apart from the substrate to form the hexagonal boron nitride film on the surface of the substrate by plasma CVD using plasma diffused from the plasma generation region.

### TECHNICAL FIELD

The present disclosure relates to a method and a device for forming a hexagonal boron nitride film.

### BACKGROUND

Hexagonal boron nitride (h-BN) is a two-dimensional material having a honeycomb-shaped crystal structure, and is an insulator having various excellent properties. Therefore, the application of h-BN thinly formed on a substrate with a thickness of one to several atomic layers to semiconductor devices or the like is being studied.

As a method for producing an h-BN film, a CVD method disclosed in Patent Documents 1 and 2, or a plasma CVD method disclosed in the prior art of Patent Document 3 and in Patent Document 4 is known.

### PRIOR ART DOCUMENTS

### Patent Documents

Patent Document 1: Japanese Patent Application Publication No. S63-145777
Patent Document 2: Japanese Patent Application Publication No. 2009-298626
Patent Document 3: Japanese Patent Application Publication No. 2002-16064
Patent Document 4: Japanese Patent Application Publication No. S61-149478

### SUMMARY

### Problems to Be Resolved by the Invention

The present disclosure provides a method and a device capable of forming a hexagonal boron nitride film having good crystallinity at a relatively low temperature.

### Means of Solving the Problems

A method for forming a hexagonal boron nitride film, according to one aspect of the present disclosure, comprises preparing a substrate, and generating plasma of a boron-containing gas and a nitrogen-containing gas in a plasma generation region located apart from the substrate and forming a hexagonal boron nitride film on a surface of the substrate by plasma CVD using plasma diffused from the plasma generation region.

### Effect of the Invention

In accordance with the present disclosure, there are provided a method and a device capable of forming a hexagonal boron nitride film having good crystallinity at a relatively low temperature.

### BRIEF DESCRIPTION OF THE DRAWINGS

FIG. 1 is a flowchart showing an embodiment of a method for forming an h-BN film.

FIG. 2 is a cross-sectional view showing a state in which an h-BN film is formed on a substrate by the embodiment of the method for forming an h-BN film.

FIG. 3 is a cross-sectional view showing an example of a processing apparatus that can be applied to perform the embodiment of the method for forming an h-BN film.

FIG. 4 shows a temperature chart in the case of forming an h-BN film of Samples 1 and 2 of Test Example 1.

FIG. 5 shows Raman spectra of Samples 1 and 2.

FIG. 6 shows TEM images of Sample 1.

FIG. 7 shows TEM images of Sample 2.

FIG. 8 shows Raman spectra of Samples 3 and 4.

FIG. 9 shows TEM images of Sample 3.

FIG. 10 shows spectra of B1s in XPS analysis of Sample 1.

FIG. 11 shows spectra of N1s in the XPS analysis of Sample 1.

FIG. 12 shows spectra of O1s in the XPS analysis of Sample 1.

FIG. 13 shows composition analysis results in a depth direction by the XPS analysis of Sample 1.

FIG. 14 shows spectra of B1s in XPS analysis of Sample 5.

FIG. 15 shows spectra of N1s in the XPS analysis of Sample 5.

FIG. 16 shows spectra of O1s in the XPS analysis of Sample 5.

FIG. 17 shows composition analysis results in the depth direction by the XPS analysis of Sample 5.

### DETAILED DESCRIPTION

Hereinafter, embodiments will be described in detail with reference to the accompanying drawings.

<Background and Outline>

First, the background and the outline will be described. Patent Documents 1 and 2 disclose, as a method for forming a hexagonal boron nitride (h-BN) film, a CVD method using a boron compound such as diborane (B₂H₆) or the like and a nitrogen compound such as ammonia (NH₃) or the like. However, a film forming temperature is about 700° C. to 1700° C., which is high, and the crystallinity is not sufficient.

Although Patent Document 3 discloses, as a prior art, a technique for forming an h-BN film by a plasma CVD method using B₂H₆ and NH₃, it is unclear whether an h-BN film having good crystallinity can be obtained. Patent Document 4 discloses film formation by plasma CVD in which plasma of a borazine gas is generated using a coil in a processing chamber and a DC voltage is applied to a substrate. However, a high temperature of 1000° C. or higher is required to form an h-BN film having good crystallinity.

On the other hand, in one aspect of the present disclosure, the substrate is located at a position apart from a plasma generation region, and the plasma CVD is performed using plasma diffused from the plasma generation region, i.e., so-called remote plasma. Accordingly, plasma mainly formed of radicals having high energy and low electron temperature can reach the substrate, and CVD reaction can be promoted to form an h-BN film having good crystallinity at a relatively low temperature.

<One Embodiment of the Method for Forming an h-BN Film>

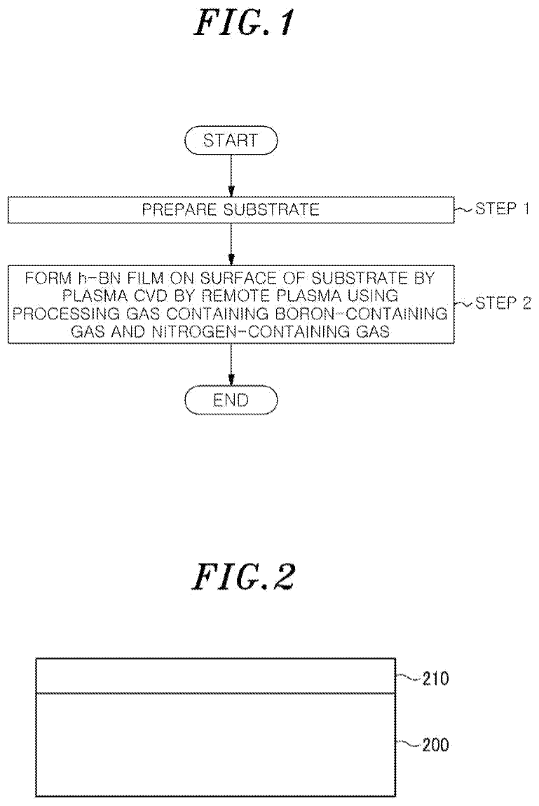

FIG. 1 is a flowchart showing an embodiment of a method for forming an h-BN film. As shown in FIG. 1, one embodiment of the method for forming an h-BN film includes: preparing a substrate (step 1); and forming an h-BN film on a surface of the substrate by plasma CVD using remote plasma of a processing gas including a boron-containing gas and a nitrogen-containing gas (step 2).

The substrate in step 1 is not particularly limited, but may be a semiconductor substrate such as a silicon substrate or the like. The surface on which the h-BN film is formed may be a semiconductor such as Si or an insulator such as SiO₂. When the surface is a semiconductor, only the semiconductor substrate may be used as the substrate. When the surface is SiO₂, the semiconductor substrate having an SiO₂ film formed on a surface thereof may be used as the substrate. Further, the substrate may or may not have a metal layer having a catalytic function on the surface thereof. The catalyst metal may be, e.g., a transition metal such as Ni, Fe, Co, Ru, Au, or the like, or an alloy containing these metals. In the case of using the metal layer having the catalytic function, the metal layer is activated by activation treatment and used. By using the metal layer having the catalytic function, it is possible to form an h-BN film having good crystallinity at a lower temperature in subsequent step 2.

In step 2, the substrate is accommodated in the processing chamber, and the remote plasma of the processing gas including the boron-containing gas and the nitrogen-containing gas acts on the substrate. Accordingly, as shown in FIG. 2, an h-BN film 210 grows on a substrate 200.

Specifically, the substrate 200 is disposed in the processing chamber, and the plasma of the processing gas including the boron-containing gas and the nitrogen-containing gas is generated at a position apart from the substrate 200 by an appropriate method. Accordingly, the plasma diffused from the plasma generation region acts on the substrate 200.

Since the plasma diffused from the plasma generation region is plasma mainly formed of radicals having high energy and low electron temperature, it is possible to promote the CVD reaction by the boron-containing gas and the nitrogen-containing gas on the surface of the substrate. Therefore, an h-BN film having good crystallinity can be formed at a relatively low temperature. Further, the h-BN film can be formed even when the catalyst metal layer does not exist. Further, since the plasma has a low electron temperature, the plasma damage to a base is small.

In this case, the plasma generation method is not particularly limited. For example, inductively coupled plasma or capacitively coupled plasma can be used. The processing gas may contain a noble gas as a plasma generating gas. In the case of using the noble gas as the plasma generating gas, it is preferable to generate plasma of the noble gas and then dissociate the boron-containing gas and the nitrogen-containing gas using the plasma of the noble gas.

The noble gas may be Ar, He, Ne, Kr, Xe or the like. Among these gases, Ar capable of stably generating plasma is preferably used. The noble gas can also be used as a purge gas. N₂ gas may be used as the purge gas.

The boron-containing gas may include diborane (B₂H₆) gas, boron trichloride (BCl₃) gas, alkyl borane gas, decaborane gas, or the like. The alkylborane gas may be trimethylborane (B(CH₃)₃) gas, triethylborane (B(C₂H₅)₃) gas, a gas represented by B(R1) (R2) (R3), B(R1) (R2)H, and B(R1)H₂ (R1, R2 and R3 being alkyl groups), or the like. Among these gases, B₂H₆ gas can be preferably used.

The nitrogen-containing gas may be NH₃ gas, a hydrazine-based compound gas containing hydrazine gas, or the like. Among these gases, NH₃ gas can be preferably used.

Further, a hydrogen-containing gas such as H₂ gas may be introduced as the processing gas. The quality of the h-BN film can be improved by using the hydrogen-containing gas.

As the process conditions of the present embodiment, the temperature of the substrate is preferably within a range of 600° C. to 800° C., e.g., 700° C., and the pressure in the processing chamber is preferably within a range of 13 Pa to 2600 Pa (0.1 Torr to 20 Torr), e.g., 1400 Pa.

Prior to the formation of the h-BN film by plasma CVD in step 2, surface treatment for cleaning the substrate surface may be performed. The surface treatment may be, e.g., treatment of supplying H₂ gas while heating the substrate to the same temperature as that in step 2. At this time, the noble gas may be added or plasma may be generated.

The h-BN film formed by the method of the present embodiment has good crystallinity and may obtain excellent characteristics of h-BN, such as excellent surface flatness at the atomic level, a high insulating property, chemical/thermal stability, a low dielectric constant, or the like.

<Application to Devices>

The h-BN film formed by the method of the present embodiment has good crystallinity, and thus can exhibit the above-described various characteristics inherent in h-BN and can be applied to various devices such as a semiconductor device and the like.

For example, by laminating the h-BN film with a graphene film, a semiconductor device can exhibit excellent characteristics. Similarly to h-BN, graphene is a two-dimensional material having a honeycomb-shaped (six-membered ring structure) crystal structure and a lattice constant similar to that of h-BN, and is a conductor having various excellent characteristics such as mobility that is higher than that of silicon by 100 times or more. Therefore, extremely high mobility can be obtained by applying graphene to a gate electrode, for example.

As described above, the h-BN film produced by the method of the present embodiment has high flatness and has a crystal structure similar to that of graphene. Therefore, by forming a graphene film as a gate electrode on the h-BN film, extremely high mobility can be obtained. Specifically, it is possible to obtain the mobility that is several times higher than that in the case of using SiO₂ film as the gate insulating film.

Further, it is known that the graphene film can be formed by the plasma CVD, and it is also possible to form the h-BN film by the method of the present embodiment and then continuously form the graphene film.

<Processing Device>

Next, an example of a processing device that can be applied to implement the embodiment of the above-described method for forming an h-BN film will be described.

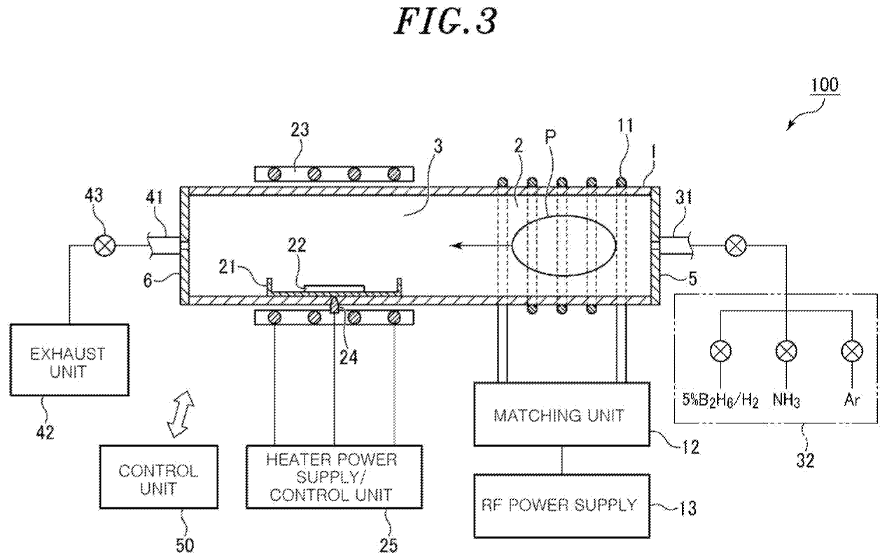

FIG. 3 is a cross-sectional view schematically showing an example of a processing device.

The processing device 100 includes a cylindrical processing chamber 1 disposed so that its axial direction is horizontal. The processing chamber 1 is made of a heat-resistant dielectric material, e.g., as quartz or ceramic. In the processing chamber 1, a plasma generation region 2 and a substrate placement region 3 are separated from each other. One end and the other end of the processing chamber 1 are closed by lids 5 and 6, respectively.

A coil-shaped antenna 11 is wound around an outer circumference of the processing chamber 1 corresponding to the plasma generation region 2, and an RF power supply 13 is connected to the antenna 11 via a matching unit 12. The RF power supply 13 has a frequency of, e.g., 13.56 MHz, and supplies a variable power. The matching unit 12 matches an internal (or output) impedance of the RF power supply 13 with a load impedance. By supplying the power from the RF power supply 13 to the coil-shaped antenna 11, induced electric field is generated in the plasma generation region 2.

A tray 21 is disposed in the substrate placement region 3 in the processing chamber 1, and a substrate 22 is accommodated in the tray 21. A heater 23 is disposed on an outer circumference of the processing chamber 1 corresponding to the substrate placement region 3. Further, a thermocouple 24 for temperature measurement is disposed on a back surface side of the substrate 22. The heater 23 and the thermocouple 24 are connected to a heater power supply/control unit 25. The heater power supply/control unit 25 can supply a power to the heater 23 and control a temperature of the substrate 22 based on a signal from the thermocouple 24.

A gas supply line 31 is connected to the end of the processing chamber 1 on the plasma generation region 2 side. The processing device 100 further includes a processing gas supply unit 32, and the processing gas is supplied from the processing gas supply unit 32 into the processing chamber 1 through the gas supply line 31. The processing gas supply unit 32 supplies a boron-containing gas, a nitrogen-containing gas, and a noble gas. Here, an example of using 5% B₂H₆/H₂ gas as the boron-containing gas, NH₃ gas as the nitrogen-containing gas, and Ar gas as the noble gas is described. These processing gases are turned into inductively coupled plasma P by the induced electric field generated in the plasma generation region 2 in the processing chamber 1.

An exhaust line 41 is connected to the end of the processing chamber 1 on the substrate placement region 3 side, and an exhaust unit 42 is connected to the exhaust line 41. A pressure control valve 43 is interposed in the exhaust line 41. The inside of the processing chamber 1 is evacuated by the exhaust unit 42. At this time, the pressure in the processing chamber 1 is controlled to a predetermined pressure by controlling the exhaust operation using the pressure control valve 43 based on a pressure detected by the pressure gauge (not shown).

The processing device 100 has a control unit 50. The control unit 50 is typically a computer and controls individual components of the processing device 100. The control unit 50 includes a storage unit that stores a process sequence of the processing device 100 and a process recipe that is a control parameter, an input device, a display, or the like, and can perform predetermined control based on the selected process recipe.

When forming an h-BN film by the processing device 100 configured as described above according to the above-described embodiment, first, any of the lids 5 and 6 is opened, and the substrate 22 is loaded into the processing chamber 1 and accommodated in the tray 21. Then, the opened lid is closed, the inside of the processing chamber 1 is evacuated by the exhaust unit 42. Next, the pressure in the processing chamber 1 is controlled to 13 Pa to 2600 Pa (0.1 Torr to 20 Torr) by the pressure control valve 43. The temperature of the substrate in the processing chamber 1 is heated and controlled to 600° C. to 800° C., e.g., 700° C., by the heater 23.

Next, the inductively coupled plasma P is generated in the plasma generation region 2 by supplying Ar gas from the processing gas supply unit 32 into the processing chamber 1 and applying the RF power from the RF power supply 13 to the coil-shaped antenna 11. When the plasma is ignited, 5% B₂H₆/H₂ gas and NH₃ gas are supplied from the processing gas supply unit 32 into the processing chamber 1 and converted into plasma.

The inductively coupled plasma P generated in the plasma generation region 2 is diffused to the substrate placement region 3 by the exhaust flow, and the diffused plasma, i.e., so-called remote plasma, acts on the substrate 22. Since the plasma diffused from the plasma generation region 2 is plasma mainly formed of radicals having high energy and low electron temperature, it is possible to promote the CVD reaction by the B₂H₆ gas and the NH₃ gas on the surface of the substrate 22. Therefore, an h-BN film having good crystallinity can be formed at a relatively low temperature. Further, the h-BN film can be formed even when the catalyst metal layer does not exist. Since the plasma has a low electron temperature, the plasma damage to a base is small.

### TEST EXAMPLES

Next, test examples will be described.

### Test Example 1

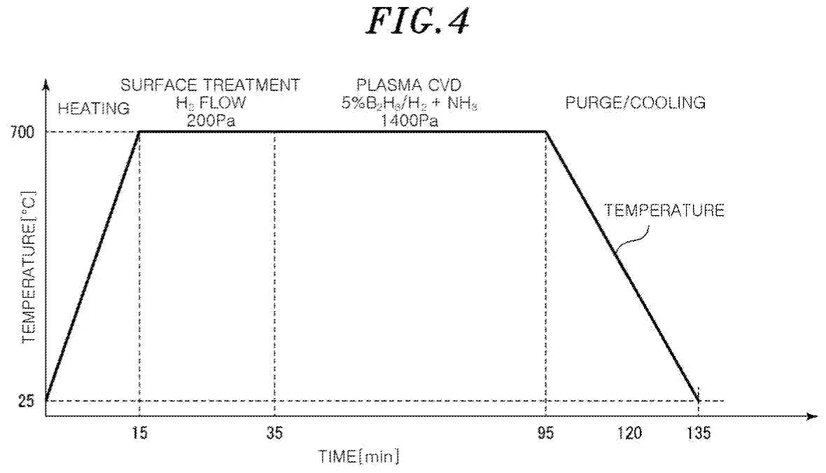

Here, a 25×25 mm substrate having a SiO₂/TiN/Ni laminated structure (Ni film thickness of 100 nm) formed on Si was set in a hot wall type processing device of FIG. 3, and B₂H₆ gas and NH₃ gas were supplied to form a film by plasma CVD using remote plasma (Sample 1). A base pressure in the processing chamber was set to 40 Pa, and a temperature of the substrate was increased to 700° C. by the heater. Then, surface treatment using H₂ gas was performed prior to plasma CVD. The temperature chart of the treatment at this time is shown in FIG. 4.

The surface treatment was performed under the conditions: temperature of 700° C., pressure of 200 Pa, H₂ gas flow rate of 100 sccm, and time of 20 min. The plasma CVD was performed under the conditions: temperature of 700° C., pressure of 1400 Pa, B₂H₆ gas flow rate of 0.1 sccm, NH₃ gas flow rate of 2.0 sccm, H₂ gas flow rate of 1.9 sccm, Ar gas flow rate of 20 sccm, RF power of 20 W, and time of 60 min.

Further, Sample (Sample 2) in which a film was formed under the same conditions as those in Sample 1 was prepared using a 25×25 mm substrate having an SiO₂ film formed on Si.

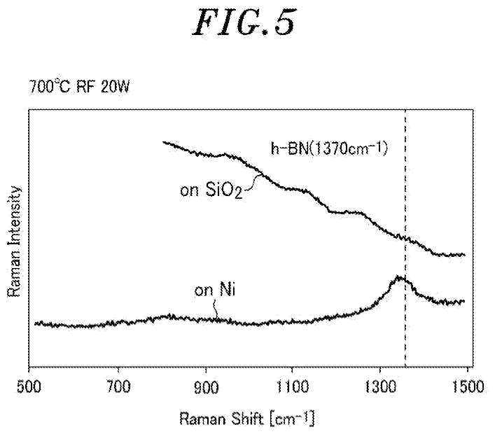

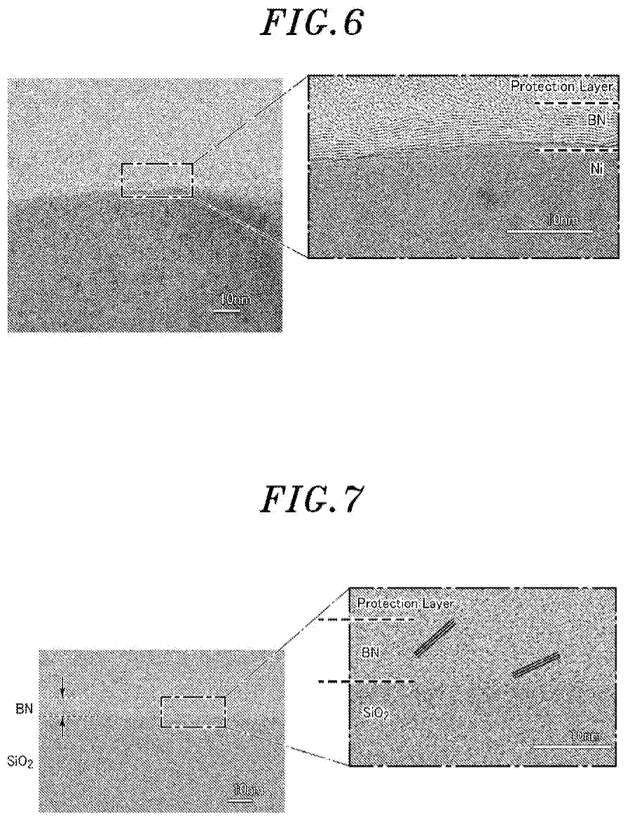

FIG. 5 shows Raman spectra of Samples 1 and 2. FIG. 6 shows TEM images of Sample 1. FIG. 7 shows TEM images of Sample 2.

As shown in FIG. 5, in Sample 1, the peak of h-BN is clearly present at 1370 cm¹ in the Raman spectrum. As shown in FIG. 6, the formation of a BN layer structure (crystal) on an Ni interface was confirmed. Further, by the element mapping of TEM-EESL, elements of B and N were confirmed on the Ni surface, and it was confirmed that the formed layered structure was h-BN.

Further, as shown in FIG. 5, in Sample 2, the peak of h-BN of the Raman spectrum was lower than that in Sample 1. Although FIG. 7 shows the formation of the BN layer on the SiO₂ interface, it was confirmed that the layer growth direction is random compared to that on Ni, and most of BN is amorphous.

For comparison, Samples (Samples 3 and 4) in which B₂H₆ gas and NH₃ gas were supplied to the same substrate as that in Samples 1 and 2 to form a film by thermal CVD without using plasma were prepared. Here, the surface treatment and the CVD film formation were performed while setting the temperature of the substrate to 900° C. The surface treatment was performed under the conditions: temperature of 900° C., pressure of 22 Pa; H₂ gas flow rate of 100 sccm, and time of 20 min. The thermal CVD was performed under the conditions: temperature of 900° C., pressure of 20 Pa, B₂H₆ gas flow rate of 1 sccm, NH₃ gas flow rate of 20 sccm, H₂ gas flow rate of 19 sccm, and time of 15 min.

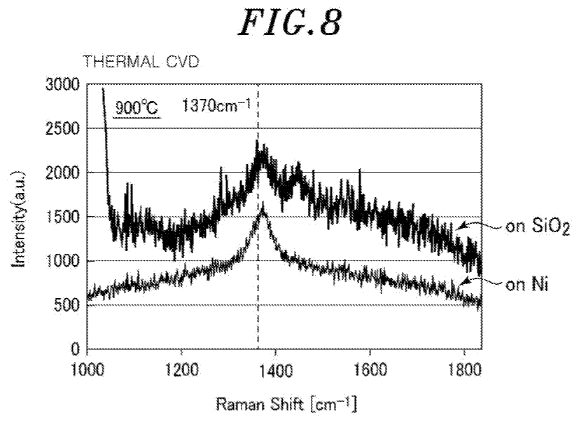

FIG. 8 shows Raman spectra of Samples 3 and 4, and FIG. 9 shows TEM images of Sample 3. FIG. 9 also shows FFT patterns of the TEM. As shown in FIG. 8, although the Raman spectra of Sample 3 show the peak of h-BN, it was confirmed that most of BN is amorphous in Sample 4. As shown in FIG. 9, it was confirmed that a layered BN was formed on the Ni interface but most of BN was amorphous and it is difficult to form an h-BN film at a temperature lower than 900° C.

### Test Example 2

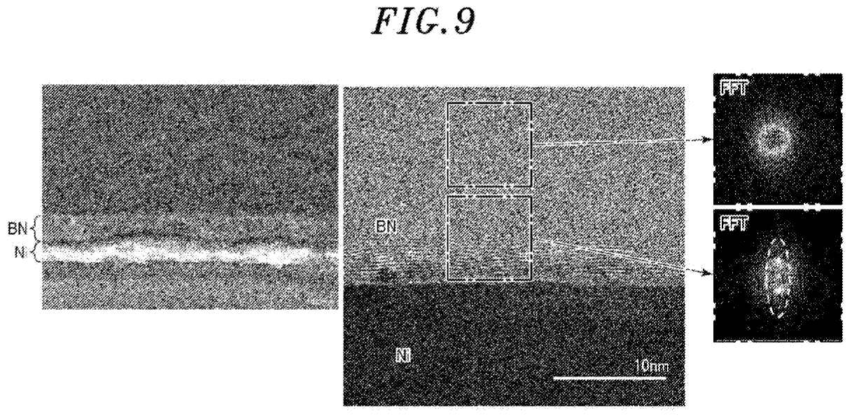

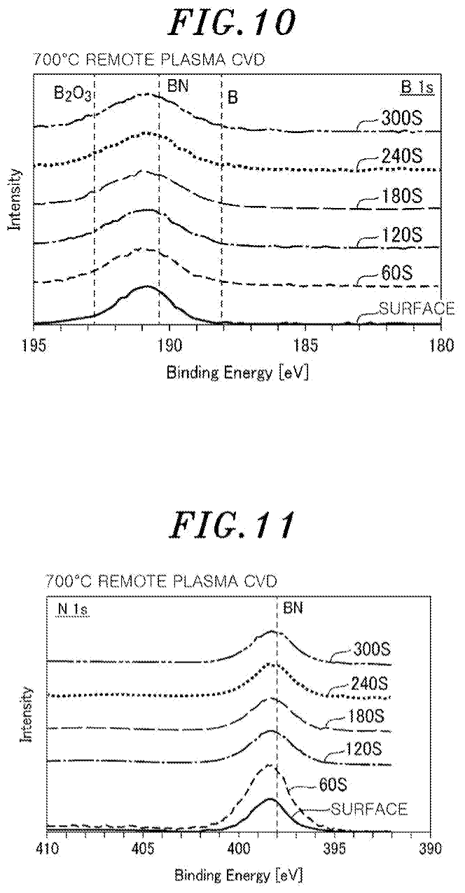

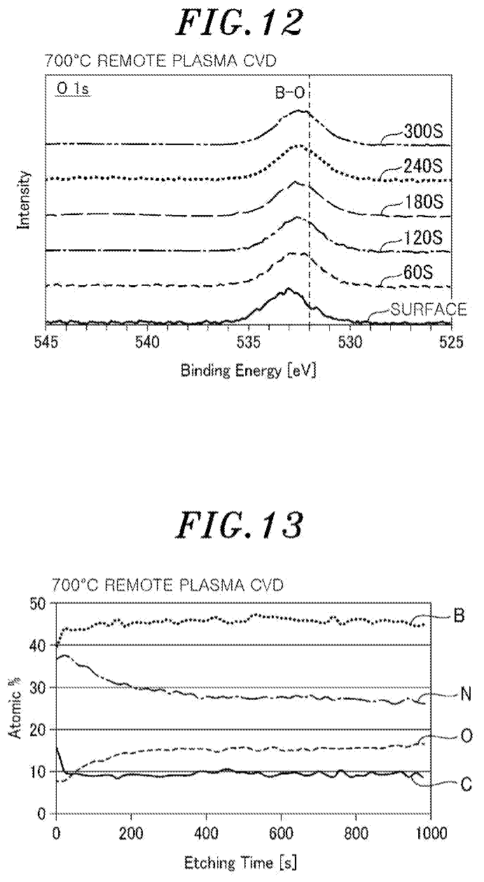

Next, XPS analysis was performed on the h-BN film of Sample 1 formed by the plasma CVD using the remote plasma. FIG. 10 shows spectra of B1s of Sample 1. FIG. 11 shows spectra of N1s of Sample 1. FIG. 12 shows spectra of O1s of Sample 1. FIG. 13 shows composition analysis results in a depth direction by the XPS analysis of Sample 1.

As shown in FIGS. 10 to 13, in Sample 1 in which the film was formed by the plasma CVD using the remote plasma, it was confirmed that B in the h-BN film was mainly bonded with N although the film forming temperature was relatively low, e.g., 700° C.

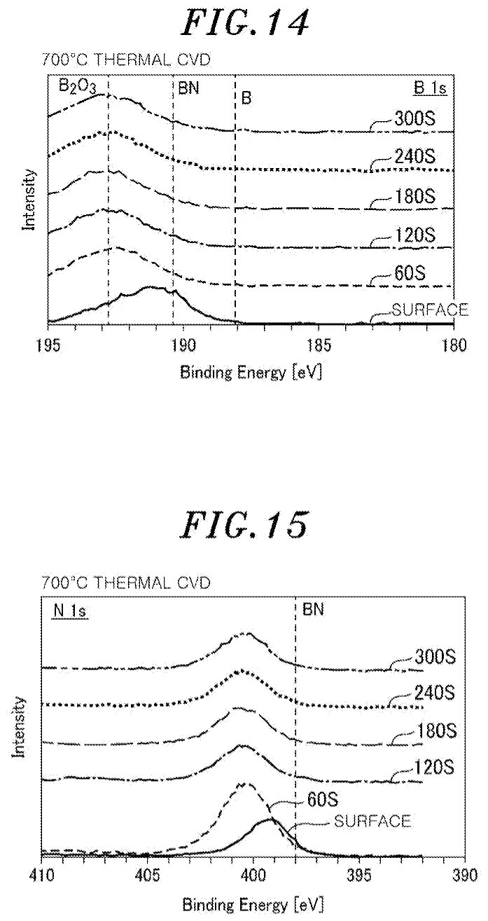

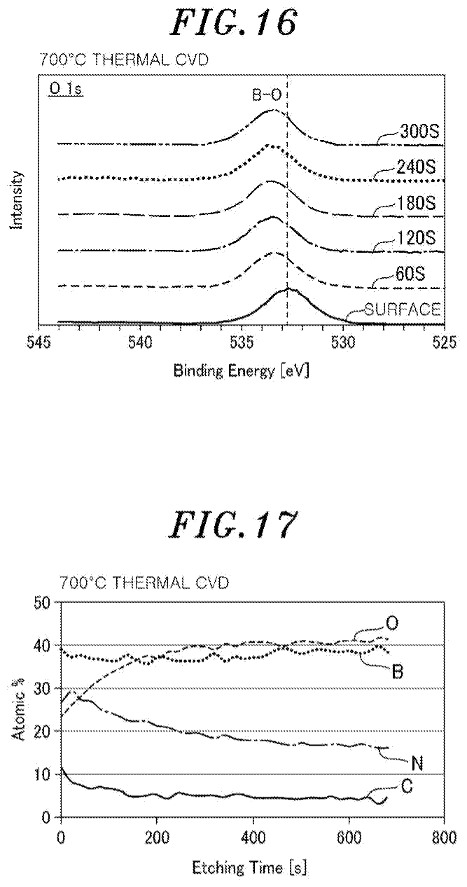

For comparison, the XPS analysis was performed on Sample 5 in which the film is formed by thermal CVD under the same conditions as those of Sample 3 except that the temperature was set to 700° C. FIG. 14 shows spectra of B1s of Sample 5. FIG. 15 shows spectra of N1s of Sample 5. FIG. 16 shows spectra of O1s of Sample 5. FIG. 17 shows composition analysis results in the depth direction by the XSP analysis of Sample 5.

As shown in FIGS. 14 to 17, in Sample 5 in which the film was formed at 700° C. by the thermal CVD, it was confirmed that B in the film was mainly bonded with O to form an oxide.

### OTHER APPLICATIONS

While the embodiments have been described above, the embodiments of the present disclosure are illustrative in all respects and are not restrictive. Further, the above-described embodiments may be omitted, replaced, or changed in various forms without departing from the scope of the appended claims and the gist thereof.

For example, in the above-described embodiments, inductively coupled plasma was used. However, the plasma generation method is not limited thereto. Further, the processing device is not limited to the device of FIG. 3, and processing devices of various configurations may be used.

Although a semiconductor substrate having a semiconductor base such as Si or the like was described as an example of the substrate for forming an h-BN film, the present disclosure is not limited thereto.

### DESCRIPTION OF REFERENCE NUMERALS

1: processing chamber
2: plasma generation region
3: substrate placement region
11: coil-shaped antenna
13: RF power supply
22: substrate
23: heater
32: processing gas supply unit
42: exhaust unit
50: control unit
100: processing device
200: substrate
210: h-BN film

1. A method for forming a hexagonal boron nitride film, comprising:
preparing a substrate; and
generating plasma of a boron-containing gas and a nitrogen-containing gas in a plasma generation region located apart from the substrate, and forming a hexagonal boron nitride film on a surface of the substrate by plasma CVD using plasma diffused from the plasma generation region.

2. The method of claim 1, wherein the surface of the substrate is a metal layer having a catalytic function.

3. The method of claim 1, wherein the surface of the substrate is a semiconductor or an insulator.

4. The method of claim 1, wherein the hexagonal boron nitride film is formed by setting a temperature of the substrate to be within a the range of 600° C. to 800° C.

5. The method of claim 1, wherein the hexagonal boron nitride film is formed by setting a pressure to be within a range of 13 Pa to 2600 Pa.

6. The method of claim 1, wherein when the hexagonal boron nitride film is formed, the plasma generated in the plasma generation region is inductively coupled plasma.

7. The method of claim 6, wherein the inductively coupled plasma is generated in the plasma generation region in a processing chamber by disposing an antenna outside the processing chamber made of a dielectric and supplying a high frequency power to the antenna.

8. The method of claim 1, wherein the boron-containing gas is a diboran gas and the nitrogen-containing gas is an ammonia gas.

9. A device for forming a hexagonal boron nitride film, comprising:
a processing chamber in which a plasma generation region in which plasma is generated and a substrate placement region in which a substrate is disposed are separated from each other;
a heater configured to heat the substrate disposed in the substrate placement region;
a plasma generator configured to generate plasma in the plasma generation region;
a gas supply device configured to supply a processing gas including a boron-containing gas and a nitrogen-containing gas into the processing chamber; and
an exhaust configured to exhaust the inside of the processing chamber,
wherein plasma of the boron-containing gas and the nitrogen-containing gas is generated in the plasma generation region by the plasma generator, and a hexagonal boron nitride film is formed on a surface of the substrate by plasma CVD using plasma diffused from the plasma generation region.
